(19) United States
(12) Patent Application Publication
(10) Pub. No.: US 2024/0258332 A1
(43) Pub. Date: Aug. 1, 2024

(54) ARRAY SUBSTRATE AND DISPLAY PANEL

(71) Applicant: Guangzhou China Star Optoelectronics Semiconductor Display Technology Co., LTd., Guangzhou (CN)

(72) Inventors: Wen SHI, Guangzhou (CN); Juan XIAO, Guangzhou (CN)

(73) Assignee: Guangzhou China Star Optoelectronics Semiconductor Display Technology Co., LTd., Guangzhou (CN)

(21) Appl. No.: 18/523,781

(22) Filed: Nov. 29, 2023

(30) Foreign Application Priority Data
Jan. 31, 2023 (CN) 202310073190.9

(51) Int. Cl. H01L 27/12; H01L 25/16

(52) U.S. Cl. CPC H01L 27/124; H01L 25/167

(57) ABSTRACT

The present disclosure provides an array substrate and a display panel containing the array substrate. The array substrate includes a pixel area and a fan-out area. The pixel area includes a plurality of thin film transistors arranged in a multi-row and multi-column array. The fan-out area includes a plurality of sub-fan-out areas, each of the plurality of sub-fan-out areas is arranged corresponding to a row of the plurality of thin film transistors, and each of the plurality of sub-fan-out areas is connected to a row of thin film transistors corresponding to the corresponding row of thin film transistors by a plurality of M1 traces. Wherein, transverse lengths of a portion of the plurality of M1 traces in at least one of the plurality of sub-fan-out areas are the same, so that a picture uniformity of the display panel can be improved.

This disclosure claims priority to Chinese Patent Disclosure No. 202310073190.9, filed in the China National Intellectual Property Administration on Jan. 31, 2023, which is incorporated herein by reference in its entirety.

### TECHNICAL FIELD

The present disclosure relates to the field of display, and in particular to an array substrate and a display panel.

### BACKGROUND

Glass-based Mini/Micro-Light Emitting Diode (MLED) direct display products have a broad application space in conference rooms, home theaters, exhibition halls and outdoor display because of their advantages of high color gamut, high brightness and unlimited splicing. In glass based MLED direct display displays, active thin film transistors are usually used for driving, and current driving is used. Small fluctuations in current can lead to poor uniformity of MLED light emission. During the display process, compensation circuits are usually needed to compensate the thin film transistors in real time.

The sensing line, as an important signal line for Vth detection and compensation in the compensation circuit, needs to ensure that voltage and resistance for the sensing line signal of each thin film transistor are consistent, thereby ensuring that the current of each thin film transistor is consistent during operation and uniformity ensuring the uniformity of LED light emission. However, in existing technology, due to the inconsistent capacitance of multiple sensing lines, it is prone to occur inaccurate detection and uneven display of the image.

### SUMMARY

The present disclosure provides an array substrate and a display panel to solve the problem of uneven screen display in the prior art.

In one aspect, the present disclosure provides an array substrate, comprising:
a pixel area comprising a plurality of thin film transistors arranged in a multi-row and multi-column array; and
a fan-out area comprising a plurality of sub-fan-out areas, wherein each of the plurality of sub-fan-out areas is arranged corresponding to a row of the plurality of thin film transistors, and each of the plurality of sub-fan-out areas is connected to a row of thin film transistors corresponding to the corresponding row of thin film transistors by a plurality of M1 traces;
wherein, transverse lengths of a portion of the plurality of M1 traces connected to different thin film transistors in at least one of the plurality of sub-fan-out areas are the same, and the transverse lengths have a direction same as a distribution direction of a row of the plurality of thin film transistors.

In one exemplary embodiment, transverse lengths of all of the plurality of M1 traces in the at least one of the plurality of sub-fan-out areas are the same.

In one exemplary embodiment, a portion of the plurality of M1 traces in the at least one of the plurality of sub-fan-out areas span a portion of the plurality of thin film transistors.

In one exemplary embodiment, all of the plurality of M1 traces in the at least one of the plurality of sub-fan-out areas span all of the thin film transistors in a row of the plurality of thin film transistors.

In one exemplary embodiment, transverse lengths of a portion of the plurality of M1 traces in each of the plurality of sub-fan-out areas are the same.

In one exemplary embodiment, transverse lengths of all of the plurality of M1 traces in the fan-out area are the same.

In one exemplary embodiment, the array substrate further comprises a plurality of sensing lines and a plurality of via holes, each of the plurality of sensing lines comprises one or more of transverse sensing lines and one or more of longitudinal sensing lines, each of the plurality of thin film transistors is connected to a portion of the longitudinal sensing lines of each of the plurality of sensing lines, and a portion of the longitudinal sensing lines of each of the plurality of thin film transistors are connected to one or more of the plurality of M1 traces corresponding to the each of the plurality of thin film transistors through respective corresponding via holes.

In one exemplary embodiment, the plurality of via holes are arranged in parallel to avoid extended M1 traces pass through the via holes corresponding to other thin film transistors.

In one exemplary embodiment, longitudinal widths of the plurality of M1 traces connected to each of the plurality of thin film transistors are the same.

In one exemplary embodiment, longitudinal width of a portion of the plurality of M1 traces in the at least one of the plurality of sub-fan-out areas are the same.

In another aspect, the present disclosure further provides a display panel comprising an array substrate, wherein the array substrate comprises:
a pixel area comprising a plurality of thin film transistors arranged in a multi-row and multi-column array; and
a fan-out area comprising a plurality of sub-fan-out areas, wherein each of the plurality of sub-fan-out areas is arranged corresponding to a row of the plurality of thin film transistors, and each of the plurality of sub-fan-out areas is connected to a row of thin film transistors corresponding to the corresponding row of thin film transistors by a plurality of M1 traces;
wherein transverse lengths of a portion of the plurality of M1 traces respectively connected to different thin film transistors in at least one of the plurality of sub-fan-out areas are the same, and the transverse lengths have a direction same as a distribution direction of a row of the plurality of thin film transistors.

In one exemplary embodiment, transverse lengths of all of the plurality of M1 traces in the at least one of the plurality of sub-fan-out areas are the same.

In one exemplary embodiment, a portion of the plurality of M1 traces in the at least one of the plurality of sub-fan-out areas span a portion of the plurality of thin film transistors.

In one exemplary embodiment, all of the plurality of M1 traces in the at least one of the plurality of sub-fan-out areas span all of the thin film transistors in a row of the plurality of thin film transistors.

In one exemplary embodiment, transverse lengths of a portion of the plurality of M1 traces in each of the plurality of sub-fan-out areas are the same.

In one exemplary embodiment, transverse lengths of all of the plurality of M1 traces in the fan-out area are the same.

In one exemplary embodiment, the array substrate further comprises a plurality of sensing lines and a plurality of via holes, each of the plurality of sensing lines comprises one or more of transverse sensing lines and one or more of longitudinal sensing lines, each of the plurality of thin film transistors is connected to a portion of the longitudinal sensing lines of each of the plurality of sensing lines, and a portion of the longitudinal sensing lines of each of the plurality of thin film transistors are connected to one or more of the plurality of M1 traces corresponding to the each of the plurality of thin film transistors through respective corresponding via holes.

In one exemplary embodiment, the plurality of via holes are arranged in parallel to avoid extended M1 traces pass through the via holes corresponding to other thin film transistors.

In one exemplary embodiment, longitudinal widths of the plurality of M1 traces connected to each of the plurality of thin film transistors are the same.

In one exemplary embodiment, longitudinal width of a portion of the plurality of M1 traces in the at least one of the plurality of sub-fan-out areas are the same.

The present disclosure provides an array substrate and a display panel. The array substrate includes a pixel area and a fan-out area. The pixel area includes a plurality of thin film transistors arranged in multi-row and multi-column array. The fan-out area includes a plurality of sub-fan-out areas, each of the plurality of sub-fan-out areas is arranged corresponding to a row of the plurality of thin film transistors, and each of the plurality of sub-fan-out areas is connected to a row of thin film transistors corresponding to the corresponding row of thin film transistors by a plurality of M1 traces. Transverse lengths of a portion of the plurality of M1 traces in at least one of the plurality of sub-fan-out areas are the same. The transverse lengths have a direction same as a direction in which a row of thin film transistors is distributed. In the present disclosure, the transverse lengths of the portion of the plurality of M1 traces in the array substrate are set to be the same, so that the contact areas between different M1 traces and other traces are the same, and then the capacitances corresponding to different M1 traces are the same, so that a same effect compensation can be realized for different of the plurality of thin film transistors, and a picture uniformity of the display panel can be improved.

### BRIEF DESCRIPTION OF FIGURES

In order to clearly explain the technical solutions in the embodiments of the present disclosure, the following context will briefly introduce the figures required in the description of the embodiments. It is clear that the figures in the following description are only some embodiments of the present disclosure. For those skilled in the art, without paying any creative effort, other figures can be obtained based on these figures.

FIG. 1 is a schematic structural diagram of an array substrate in the existing art;

FIG. 2 is a schematic structural diagram of an array substrate according to an embodiment of the present disclosure;

FIG. 3 is a schematic structural diagram of an array substrate according to another embodiment of the present disclosure.

### EMBODIMENTS OF THE PRESENT DISCLOSURE

Technical solutions in embodiments of the present disclosure will be clearly and completely described below in conjunction with drawings in the embodiments of the present disclosure. Obviously, the described embodiments are only some embodiments of the present disclosure, and not limited to the embodiments. Based on the embodiments in the present disclosure, all other embodiments obtained by those skilled in the art without creative effort fall within the protection scope of the present disclosure.

In the description of the present disclosure, it is to be understood that the terms “center,” “longitudinal,” “transverse,” “length,” “width,” “thickness,” “up,” “down,” “front,” “back,” “left,” “right,” “vertical,” “horizontal,” “top,” “bottom,” “inside,” “outside,” and the like indicate orientations or positional relationships based on those shown in the drawings and are intended only for the ease of describing and simplifying the description, rather than indicating or implying that the device or element referred to must have a specific orientation, or be constructed and operated in a particular orientation. Therefor the terms cannot be construed as limiting the present disclosure. Furthermore, the terms “first” and “second” are used for the purposes of description only and cannot be understood as indicating or implying relative importance or implying the number of technical features indicated. Thus, features defined as “first,” “second,” may explicitly or implicitly include one or more of the features. In the description of the present disclosure, “multiple/a plurality of” means two or more, unless expressly specified otherwise.

In the present disclosure, the term “exemplary”, “embodiment” is used to mean “serving as an example, illustration or illustration”. Any embodiment in the present disclosure described as “exemplary” is not necessarily construed as being more preferred or advantageous than other embodiments. The following description is given to enable any of those skilled in the art to practice and use the present disclosure. In the following description, the details are listed for the purpose of explanation. It should be understood that one of those ordinary skilled in the art will recognize that the present disclosure may be practiced without the use of these specific details. In other embodiments, known or commonly used structures and processes will not be elaborated in detail to avoid unnecessary redundancy that obscure the description of the present disclosure. For ordinary technical personnel in this field, it is clear that known or commonly used structures or features are included within the scope of this disclosure. Accordingly, the present disclosure is not intended to be limited to the embodiments shown but is consistent with the broadest scope consistent with the principles and features disclosed herein.

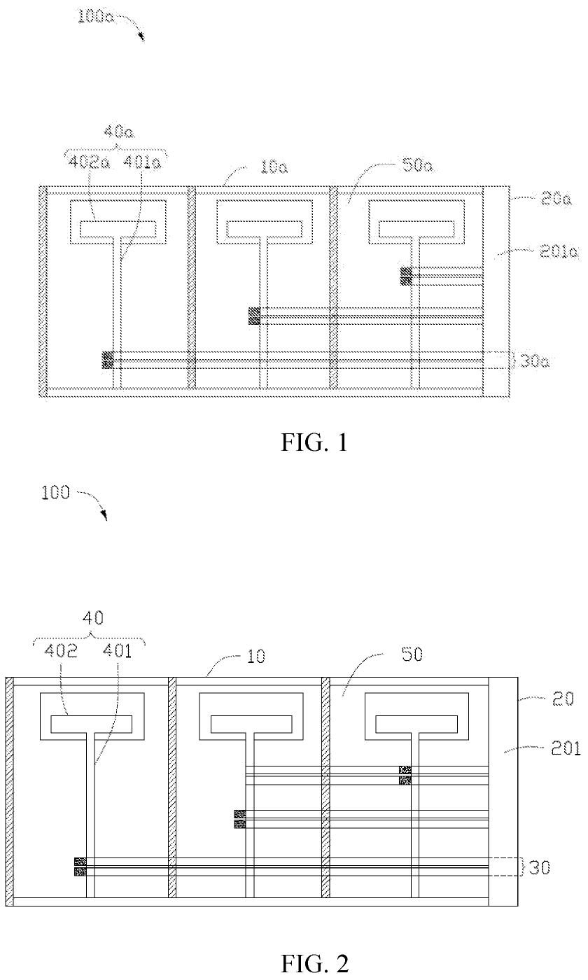

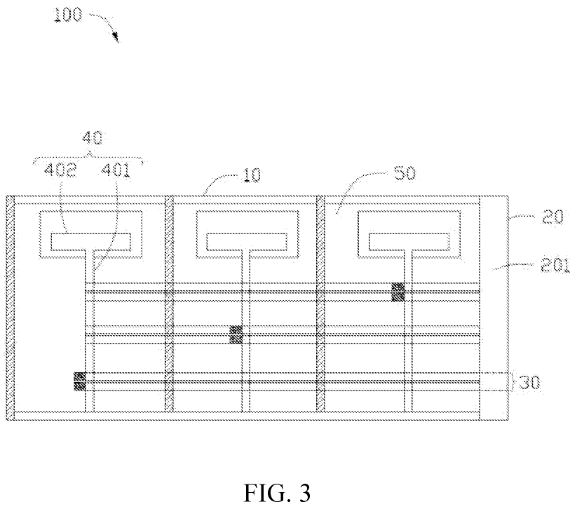

An embodiment of the present disclosure provides an array substrate and a display panel, which will be described in detail below with reference to FIG. 2 to FIG. 3.

FIG. 1 is a schematic diagram of an array substrate 100a in an existing art. The array substrate 100a in the existing art includes a pixel area 10a and a fan-out area 20a. Wherein, the pixel area 10a includes a plurality of thin film transistors (TFTs) 50a arranged in a multi-row and multi-column array which is a common arrangement of multiple thin film transistors on the array substrate 100a. The fan-out area 20a includes a plurality of traces disposed on the array substrate 100a, that is, the plurality of traces of the array substrate 100a are integrated in the fan-out area 20a and separated from the fan-out area 20a to respectively connect the plurality of thin film transistors 50a.

The plurality of thin film transistors 50a is arranged in a multi-row and multi-column array, thereby the fan-out area 20a can be divided into a plurality of sub-fan-out areas 201a. Each of the plurality of sub-fan-out areas 201a is arranged corresponding to a row of the plurality of thin film transistors 50a, and each of the plurality of sub-fan-out areas 201a is connected with a row of the plurality of thin film transistors 50a corresponding to itself through a plurality of M1 traces 30a.

In the embodiment shown in FIG. 1, each of the plurality of sub-fan-out areas 201a extends out a plurality of M1 traces 30a, and the plurality of M1 traces 30a extend into different of the plurality of thin film transistors different of the plurality of thin film transistors 50a to connect with the plurality of thin film transistors 50a in a same row. The array substrate 100a shown in FIG. 1 further includes other longitudinally arranged traces, such as a plurality of sensing lines 40a connected to the plurality of thin film transistors 50a, in addition to the plurality of M1 traces 30a arranged transversely. Each of the plurality of sensing lines 40a generally includes one or more of the longitudinal sensing lines 401a and one or more of transverse sensing lines 402a. The one or more of transverse sensing lines 402a is disposed above the plurality of thin film transistors 50a and is directly connected with the plurality of thin film transistors 50a. The one or more of the longitudinal sensing lines 401a is connected to one or more of the plurality of M1 traces 30a corresponding to each of the plurality of thin film transistors 50a. The one or more of the longitudinal sensing lines 401a corresponding to each of the plurality of thin film transistors 50a and one or more of the plurality of plurality of M1 traces 30a corresponding to the each of the plurality of thin film transistors 50a are connected through one or more of the plurality of via holes 60 a.

For the array substrate 100a in the existing art shown in FIG. 1, the fan-out area 20a is generally disposed at an edge portion of the array substrate 100a, thereby when one or more of the plurality of M1 traces 30a extends into the interior of the array substrate 100a to connect one or more of the plurality of thin film transistors 50a, the one or more of the plurality of M1 traces 30a corresponding to different traces of the plurality of thin film transistors 50a span multiple of the plurality of thin film transistors 50a. Referring to FIG. 1, taking leftmost thin film transistors of FIG. 1 as an example, when the fan-out area 20a is arranged on a right side of the array substrate 100a, the M1 traces 30a corresponding to the leftmost thin film transistor 50a extends from the right side of the array substrate 100a to the left side of the array substrate 100a, and at this time the M1 traces 30a corresponding to the leftmost thin film transistor 50a span another two thin film transistors 50a. a rightmost thin film transistors 50a can be connected without span other thin film transistors 50a. There are many traces in the plurality of thin film transistors 50a, which resulting in overlap between the plurality of M1 traces 30a connected to different of the plurality of thin film transistors different of the plurality of thin film transistors 50a and other traces. A capacitance may be generated by overlapping traces. Because a number of overlapping traces and an area of overlapping traces are different, the capacitances generated are also different. However, capacitances of different sizes affect a subsequent compensation of a display panel.

In order to solve the above problems, the present disclosure provides an array substrate 100. FIG. 2 is a schematic structural diagram of an embodiment of the array substrate 100 provided by an embodiment of the present disclosure. A structure of the array substrate 100 provided by the embodiment of the present disclosure is substantially similar to that of the array substrate 100a in the existing art, the array substrate 100 includes a pixel area 10 and a fan-out area 20. The pixel area 10 includes a plurality of thin film transistors 50 arranged in a multi-row and multi-column array. The fan-out area 20 includes a plurality of sub-fan-out areas 201, each of the plurality of sub-fan-out areas 201 is arranged corresponding to a row of the plurality of thin film transistors 50, and each of the plurality of sub-fan-out areas 201 is connected to a row of thin film transistors 50 corresponding to the corresponding row of thin film transistors by a plurality of M1 traces 30.

Unlike the array substrate 100a of the existing art, in the array substrate 100 provided in the present disclosure, transverse lengths of a portion of the plurality of M1 traces 30 respectively connected to different of the plurality of thin film transistors 50 in at least one of the plurality of sub-fan-out areas 201 are the same. That is, each of the plurality of sub-fan-out areas 201 includes a plurality of M1 traces 30 respectively connected to different of the plurality of thin film transistors 50, in the present disclosure, transverse lengths of the portion of the plurality of M1 traces 30 are set to be the same, and the portion of the plurality of M1 traces 30 having the same transverse length is one or more of the plurality of M1 traces 30 respectively connected to different of the plurality of thin film transistors 50 in a same row of the plurality of thin film transistors 50. Thereby, ensuring that a number of thin film transistors 50 spanned by one or more of the plurality of M1 traces 30 corresponding to each of the plurality of thin film transistors 50 in the same row is the same, that is, contact areas between the one or more of the plurality of M1 traces 30 corresponding to different of the plurality of thin film transistors 50 and other traces are the same, thereby capacitances corresponding to each of the plurality of thin film transistors 50 are the same. Thereby, the display panel after subsequent compensation can be uniformly displayed.

In the embodiments of the present disclosure, the array substrate 100 includes a pixel area 10 and a fan-out area 20. The pixel area 10 includes a plurality of thin film transistors 50 arranged in a multi-row and multi-column array. The fan-out area 20 includes a plurality of sub-fan-out areas 201, each of the plurality of sub-fan-out areas 201 is arranged corresponding to a row of the plurality of thin film transistors 50, and each of the plurality of sub-fan-out areas 201 is connected to a row of thin film transistors 50 corresponding to the corresponding row of thin film transistors by a plurality of M1 traces 30. Wherein, transverse lengths of a portion of the plurality of M1 traces 30 in at least one of the plurality of sub-fan-out areas 201 are the same. The transverse lengths have a direction same as a direction in which a row of thin film transistors 50 is distributed. In the present disclosure, the transverse lengths of the portion of the plurality of M1 traces 30 in the array substrate 100 are set to be the same, so that the contact areas between different M1 traces 30 and other traces are the same, and then the capacitances corresponding to different M1 traces 30 are the same, so that a same effect compensation can be realized for different of the plurality of thin film transistors 50, and a picture uniformity of the display panel can be improved.

Referring to FIG. 1, each of the plurality of sub-fan-out areas 201 includes a plurality of M1 traces 30, and the plurality of M1 traces 30 are respectively connected to multiple thin film transistors 50 in the same row of the plurality of thin film transistors 50. In the present disclosure, lengths of at least two of the plurality of M1 traces 30 in one of the plurality of sub-fan-out areas 201 are set to be the same, thereby ensuring that capacitances generated by the contact of M1 traces 30 of different of the plurality of thin film transistors 50 with other traces are the same. Taking the rightmost thin film transistor 50 in FIG. 1 as an example, the M1 traces 30a corresponding to the rightmost thin film transistor 50a in the existing art only extends from the sub-fan-out area 201a to the rightmost thin film transistor 50a. However, in the present disclosure, the transverse lengths of the portion of the plurality of M1 traces 30 corresponding to the rightmost thin film transistor 50 continue to be extended, so that the transverse lengths of the M1 traces 30 corresponding to the rightmost thin film transistor 50 are the same as the transverse lengths of the portion of the plurality of M1 traces 30 corresponding to the intermediate thin film transistor 50. Thus, a number of traces spanned by the M1 traces 30 corresponding to the intermediate thin film transistor 50 is the same as the number of traces spanned by the M1 traces 30 corresponding to the rightmost thin film transistor 50. The contact areas between the M1 traces 30 corresponding to each of the two thin film transistors 50 and the other traces are also the same, so as to control the capacitances generated are also the same.

It is necessary in the present disclosure to define a portion of the plurality of M1 traces 30 connected to different of the plurality of thin film transistors 50 in a sub-fan-out area 201 to have a same transverse length, rather than defining a portion of the plurality of M1 traces 30 connected to different of the plurality of thin film transistors 50 in the entire array substrate 100 to have a same transverse length, that is because in an actual array substrate, the thin film transistors and the M1 traces respectively connecting to the thin film transistors in the array substrate have the structure shown in FIG. 2. In fact, there are M1 traces 30 that connected to a portion of the plurality of thin film transistors 50 have a same transverse length between different sub-fan-out areas 201. For example, in two adjacent rows of the plurality of thin film transistors 50, transverse lengths of the portion of the plurality of M1 traces 30 corresponding to two rightmost thin film transistors 50 are the same, therefore, there is no need to limit or adjust again. Therefore, the present disclosure limits that portions of M1 traces 30 separately connected to different of the plurality of thin film transistors 50 in the same sub-fan-out area 201 have a same transverse length.

It should be noted that, in the present disclosure, by actually extending the transverse lengths of a portion of the plurality of M1 traces 30, the contact areas between the portion of the plurality of M1 traces 30 and other traces can be increased. Only extending transverse lengths of M1 traces 30 cannot guarantee same capacitances corresponding to each of the plurality of thin film transistors 50, thereby, in the present disclosure, the transverse lengths of M1 traces 30 corresponding to at least a portion of the thin film transistors 50 in the same row are set to be the same, so as to ensure the same capacitance. By limiting the same transverse lengths of the portion of the plurality of M1 traces 30 corresponding to the portion of the plurality of thin film transistors 50 in the same row, a picture uniformity corresponding to the portion of the plurality of thin film transistors 50 can be improved in a certain extent.

One sub-fan-out area 201 is generally connected to two or more thin film transistors 50, so that in other embodiments, transverse lengths of all of the plurality of M1 traces 30 in at least one of the plurality of sub-fan-out areas 201 can be set to be the same. FIG. 3 is a schematic structural diagram of another embodiment of the array substrate 100 provided by an embodiment of the present disclosure. As is shown in FIG. 3, a row of the plurality of thin film transistors 50 in the array substrate 100 includes three thin film transistors 50, and each of the three thin film transistors 50 connects to one or more of M1 traces 30. In the embodiment shown in FIG. 3, the transverse lengths of the portion of the plurality of M1 traces 30 of the three thin film transistors 50 in the same row are all the same. Thereby ensuring that capacitances corresponding to the three thin film transistors 50 in the same row is the same, which in turn ensures that a subsequent compensation can make the picture of this row uniform.

It should be noted that, the plurality of thin film transistors 50 are arranged in array, and each of the plurality of thin film transistors 50 needs to be connected to M1 traces 30 corresponding thereof to realize various functions, thereby, the transverse lengths of the portion of the plurality of M1 traces 30 corresponding to each of the plurality of thin film transistors 50 in the same row are set to be the same, and it is necessary to control a portion of the plurality of M1 traces 30 span multiple of the plurality of thin film transistors 50. Taking the array substrate 100 shown in FIG. 2 as an example, in order to ensure the normal operation of the plurality of thin film transistors 50, each of the plurality of thin film transistors 50 needs to be connected to M1 traces 30 corresponding thereof. Therefore, while ensuring that the transverse lengths of a portion of the plurality of M1 traces 30 are the same, the transverse lengths of the portion of the plurality of M1 traces 30 connected to the intermediate thin film transistors 50 cannot be shortened, and only the transverse lengths of the portion of the plurality of M1 traces 30 connected to the rightmost thin film transistors 50 can be extended. The extended M1 traces 30 span the rightmost thin film transistors 50 and the middle thin film transistors 50, and the M1 traces 30 corresponding to the middle thin film transistors 50 span the rightmost thin film transistors 50 and the middle thin film transistors 50. Therefore, in some embodiments of the present disclosure, a portion of the M1 traces 30 having the same transverse length, and the portion of the M1 traces 30 having the same transverse length span multiple of the plurality of thin film transistors 50.

Therefore, in the embodiments of the present disclosure, all of the plurality of M1 traces 30 in at least one of the plurality of sub-fan-out areas 201 may be made to span all of the thin film transistors 50 in a row of the plurality of thin film transistors 50. That is, the transverse lengths of all of the plurality of M1 traces 30 in at least one of the plurality of sub-fan-out areas 201 are the same with the longest transverse length of the M1 traces 30 in the at least one of the plurality of sub-fan-out areas 201. In FIG. 3, for example, the transverse lengths of a portion of the plurality of M1 traces 30 corresponding to the multiple thin film transistors 50 in the same row cross all of the thin film transistors 50 in the same row, and the transverse lengths of the portion of the plurality of M1 traces 30 corresponding to the multiple thin film transistor 50 in the same row is the same with the transverse lengths of the portion of the plurality of M1 traces 30 corresponding to the leftmost thin film transistor 50.

The above embodiments describe that the transverse lengths of a portion of the plurality of M1 traces 30 corresponding to one of the plurality of sub-fan-out areas 201 are the same. In other embodiments, structures of the plurality of sub-fan-out areas 201 may all be arranged according to the structures as shown in FIG. 2 or FIG. 3. That is, transverse lengths of a portion of the plurality of M1 traces 30 in each of the plurality of sub-fan-out areas 201 are set to be the same, or transverse lengths of all of the plurality of M1 traces 30 in each of the plurality of sub-fan-out areas 201 are set to be the same.

It should be noted again that, the M1 traces 30 with the same transverse length exist between different sub-fan-out areas 201, thereby the above embodiments describe that the transverse lengths of a portion or all of the plurality of M1 traces 30 in one sub-fan-out area 201 are the same. The plurality of sub-fan-out areas 201 are arranged according to the configuration shown in FIG. 2 or FIG. 3, rather than to set the transverse length of one of the plurality of M1 traces 30 in one of the plurality of sub-fan-out areas 201 to be the same with the transverse length of one of the plurality of M1 traces 30 in other sub-fan-out areas 201.

In at least one specifically embodiment, the transverse lengths of all of the plurality of M1 traces 30 connected to each of the plurality of thin film transistors 50 in the array substrate 100 may be set to be the same, and all of the plurality of M1 traces 30 span an entire row of the plurality of thin film transistors 50. Thus, it is possible to ensure that contact areas between the M1 traces 30 of all of the plurality of thin film transistors 50 and other traces are the same, thereby ensuring that the capacitances of each of the thin film transistors 50 are the same. The overall uniformity of the picture can be effectively improved when the picture is compensated.

The array substrate 100 further comprises a plurality of sensing lines 40 and a plurality of via holes 60. Each of the plurality of sensing lines 40 generally includes one or more of longitudinal sensing lines 401 and one or more of transverse sensing lines 402. The one or more of transverse sensing lines 402 is disposed above the plurality of thin film transistors 50 and is directly connected with the plurality of thin film transistors 50. A portion of the longitudinal sensing lines 401 are connected to one or more of the plurality of the M1 traces 30 corresponding to each of the plurality of thin film transistors 50. Each of the plurality of thin film transistors 50 is connected to one of the plurality of sensing lines 40. A portion of the longitudinal sensing lines 401 of each of the plurality of thin film transistors 50 are connected to one or more of the plurality of M1 traces 30 corresponding to the each of the plurality of thin film transistors 50 through respective corresponding via holes 60.

It should be noted that, the array substrate 100 further includes a plurality of via holes 60, and the plurality of via holes 60 are configured to connect a plurality of sensing lines and the M1 traces 30, thereby the plurality of via holes 60 need to be arranged in parallel to ensure that the plurality of M1 traces 30 are also arranged in parallel, thereby avoiding conduction problems caused by the extended M1 traces 30 pass through the via holes 60 corresponding to other thin film transistors 50. There are other structures in the array substrate 100, if there are unavoidable via holes 60 of the extended M1 traces 30, it is necessary to disconnect at the unavoidable via holes 60. Of course, the M1 traces 30 corresponding to each of the plurality of thin film transistors 50 cannot be disconnected at via hole 60 corresponding to the each of the plurality of thin film transistors 50, because the M1 traces 30 corresponding to the each of the plurality of thin film transistors 50 need to be connected to the plurality of sensing lines.

Meanwhile, the capacitance is related to the contact area, the above embodiments of the present disclosure only extend the transverse lengths of the portion of the plurality of M1 traces 30, if the capacitance of each of the plurality of thin film transistors 50 is set to be the same, it is necessary to set longitudinal width of a portion of the plurality of M1 traces 30 in the at least one of the plurality of sub-fan-out areas 201 to be the same, or it is necessary to set longitudinal width of each of the plurality of M1 traces 30 to be the same. Same transverse lengths and same longitudinal widths can ensure the same capacitance of each of the plurality of thin film transistor 50.

It should be noted that, a direction of the transverse lengths in the present disclosure generally refers to a distribution direction of a row of the plurality of thin film transistors 50. M1 trace 30 needs to span the plurality of sensing lines, thereby the direction of the transverse length may also be a direction perpendicular to the plurality of sensing lines, and longitudinal direction is a direction parallel to the plurality of sensing lines. In the present disclosure, although each of the plurality of M1 traces 30 connected to each of the plurality of thin film transistors 50 is actually includes a plurality of metal lines, transverse lengths of all of the plurality of metal lines are set to be the same regardless of how many metal lines each of the plurality of M1 traces 30 includes.

The present disclosure further provides a display panel. The display panel includes the array substrate 100 above. FIG. 2 is a schematic structural diagram of an embodiment of the array substrate 100 provided by an embodiment of the present disclosure. A structure of the array substrate 100 provided by the embodiment of the present disclosure is substantially similar to that of the array substrate 100a in the existing art, the array substrate 100 includes a pixel area 10 and a fan-out area 20. The pixel area 10 includes a plurality of thin film transistors 50 arranged in a multi-row and multi-column array. The fan-out area 20 includes a plurality of sub-fan-out areas 201, each of the plurality of sub-fan-out areas 201 is arranged corresponding to a row of the plurality of thin film transistors 50, and each of the plurality of sub-fan-out areas 201 is connected to a row of thin film transistors 50 corresponding to the corresponding row of thin film transistors by a plurality of M1 traces 30.

However, unlike the array substrate 100a of the existing art, in the array substrate 100 provided in the present disclosure, and transverse lengths of a portion of the plurality of M1 traces 30 respectively connected to different of the plurality of thin film transistors 50 in at least one of the plurality of sub-fan-out areas 201 are the same. That is, each of the plurality of sub-fan-out areas 201 includes a plurality of M1 traces 30 respectively connected to different of the plurality of thin film transistors 50, in the present disclosure, transverse lengths of the portion of the plurality of M1 traces 30 are set to be the same, and the portion of the plurality of M1 traces 30 having the same transverse length is one or more of the plurality of M1 traces 30 respectively connected to different of the plurality of thin film transistors 50 in a same row of the plurality of thin film transistors 50. A number of thin film transistors 50 spanned by one or more of the plurality of M1 traces 30 corresponding to each of the plurality of thin film transistors 50 in the same row is the same, that is, contact areas between one or more of the plurality of M1 traces 30 corresponding to different of the plurality of thin film transistors 50 and other traces are the same, so that capacitances corresponding to each of the plurality of thin film transistors 50 are the same, and the display panel after subsequent compensation can be uniformly displayed.

In the embodiments of the present disclosure, the array substrate 100 includes a pixel area 10 and a fan-out area 20. The pixel area 10 includes a plurality of thin film transistors 50 arranged in a multi-row and multi-column array. The fan-out area 20 includes a plurality of sub-fan-out areas 201, each of the plurality of sub-fan-out areas 201 is arranged corresponding to a row of the plurality of thin film transistors 50, and each of the plurality of sub-fan-out areas 201 is connected to a row of thin film transistors 50 corresponding to the corresponding row of thin film transistors by a plurality of M1 traces 30. Transverse lengths of a portion of the plurality of M1 traces 30 in at least one of the plurality of sub-fan-out areas 201 are the same. The transverse lengths have a direction same as a direction in which a row of thin film transistors 50 is distributed. In the present disclosure, the transverse lengths of the portion of the plurality of M1 traces 30 in the array substrate 100 are set to be the same, so that the contact areas between different M1 traces 30 and other traces are the same, and then the capacitances corresponding to different M1 traces 30 are the same, so that a same effect compensation can be realized for different of the plurality of thin film transistors 50, and a picture uniformity of the display panel can be improved.

Referring to FIG. 1, each of the plurality of sub-fan-out areas 201 includes the plurality of M1 traces 30, and the plurality of M1 traces 30 are respectively connected to multiple thin film transistors 50 in the same row of the plurality of thin film transistors 50. In the present disclosure, lengths of at least two of the plurality of M1 traces 30 in one of the plurality of sub-fan-out areas 201 are set to be the same, thereby ensuring that capacitances generated by the contact of M1 traces 30 of different of the plurality of thin film transistors 50 with other traces are the same. Taking the rightmost thin film transistor 50 in FIG. 1 as an example, the M1 traces 30a corresponding to the rightmost thin film transistor 50a in the existing art only extends from the sub-fan-out area 201a to the rightmost thin film transistor 50a. In the present disclosure, the transverse lengths of the portion of the plurality of M1 traces 30 corresponding to the rightmost thin film transistor 50 continue to be extended, so that the transverse lengths of the M1 traces 30 corresponding to the rightmost thin film transistor 50 are the same as the transverse lengths of the portion of the plurality of M1 traces 30 corresponding to the intermediate thin film transistor 50. Thus, a number of traces spanned by the M1 traces 30 corresponding to the intermediate thin film transistor 50 is the same as the number of traces spanned by the M1 traces 30 corresponding to the rightmost thin film transistor 50. The contact areas between the M1 traces 30 corresponding to each of the two thin film transistors 50 and the other traces are also the same, so as to control the capacitances generated are also the same.

It is necessary in the present disclosure to define a portion of the plurality of M1 traces 30 connected to different of the plurality of thin film transistors 50 in a sub-fan-out area 201 to have a same transverse length, rather than defining a portion of the plurality of M1 traces 30 connected to different of the plurality of thin film transistors 50 in the entire array substrate 100 to have a same transverse length, that is because in an actual array substrate, the thin film transistors and the M1 traces respectively connecting to the thin film transistors in the array substrate have the structure shown in FIG. 2. In fact, there are M1 traces 30 that connected to a portion of the plurality of thin film transistors 50 have a same transverse length between different sub-fan-out areas 201. For example, in two adjacent rows of the plurality of thin film transistors 50, transverse lengths of the portion of the plurality of M1 traces 30 corresponding to two rightmost thin film transistors 50 are the same, therefore, there is no need to limit or adjust again. Therefore, the present disclosure limits that portions of M1 traces 30 separately connected to different of the plurality of thin film transistors 50 in the same sub-fan-out area 201 have a same transverse length.

It should be noted that, in the present disclosure, by actually extending the transverse lengths of a portion of the plurality of M1 traces 30, the contact areas between the portion of the plurality of M1 traces 30 and other traces can be increased. However, only extending transverse lengths of M1 traces 30 cannot guarantee same capacitances corresponding to each of the plurality of thin film transistors 50, thereby, in the present disclosure, the transverse lengths of M1 traces 30 corresponding to at least a portion of the thin film transistors 50 in the same row are set to be the same, so as to ensure the same capacitance. By limiting the same transverse lengths of the portion of the plurality of M1 traces 30 corresponding to the portion of the plurality of thin film transistors 50 in the same row, a picture uniformity corresponding to the portion of the plurality of thin film transistors 50 can be improved in a certain extent.

One sub-fan-out area 201 is generally connected to two or more thin film transistors 50, so that in other embodiments, the transverse lengths of all of the plurality of M1 traces 30 in at least one of the plurality of sub-fan-out areas 201 can be set to be the same. FIG. 3 is a schematic structural diagram of another embodiment of the array substrate 100 provided by an embodiment of the present disclosure. As is shown in FIG. 3, a row of the plurality of thin film transistors 50 in the array substrate 100 includes three thin film transistors 50, and each of the three thin film transistors 50 connects to one or more of M1 traces 30. In the embodiment shown in FIG. 3, the transverse lengths of the portion of the plurality of M1 traces 30 of the three thin film transistors 50 in the same row are all the same. Thereby ensuring that capacitances corresponding to the three thin film transistors 50 in the same row is the same, which in turn ensures that a subsequent compensation can make the picture of this row uniform.

It should be noted that, the plurality of thin film transistors 50 are arranged in array, and each of the plurality of thin film transistors 50 needs to be connected to M1 traces 30 corresponding thereof to realize various functions, thereby, the transverse lengths of the portion of the plurality of M1 traces 30 corresponding to each of the plurality of thin film transistors 50 in the same row are set to be the same, and it is necessary to control a portion of the plurality of M1 traces 30 span multiple of the plurality of thin film transistors 50. Taking the array substrate 100 shown in FIG. 2 as an example, in order to ensure the normal operation of the plurality of thin film transistors 50, each of the plurality of thin film transistors 50 needs to be connected to M1 traces 30 corresponding thereof. Therefore, while ensuring that the transverse lengths of the portion of the plurality of M1 traces 30 are the same, the transverse lengths of the portion of the plurality of M1 traces 30 connected to the intermediate thin film transistors 50 cannot be shortened, and only the transverse lengths of the portion of the plurality of M1 traces 30 connected to the rightmost thin film transistors 50 can be extended. The extended M1 traces 30 span the rightmost thin film transistors 50 and the middle thin film transistors 50, and the M1 traces 30 corresponding to the middle thin film transistors 50 span the rightmost thin film transistors 50 and the middle thin film transistors 50. Therefore, in some embodiments of the present disclosure, a portion of the M1 traces 30 having the same transverse length, and the portion of the M1 traces 30 having the same transverse length span multiple of the plurality of thin film transistors 50.

Therefore, in the embodiments of the present disclosure, all of the plurality of M1 traces 30 in at least one of the plurality of sub-fan-out areas 201 may be made to span all of the thin film transistors 50 in a row of the plurality of thin film transistors 50. That is, the transverse lengths of all of the plurality of M1 traces 30 in at least one of the plurality of sub-fan-out areas 201 are the same as the longest transverse length of the M1 traces 30 in the at least one of the plurality of sub-fan-out areas 201. In FIG. 3, for example, the transverse lengths of a portion of the plurality of M1 traces 30 corresponding to the multiple thin film transistors 50 in the same row cross all of the thin film transistors 50 in the same row, and the transverse lengths of the portion of the plurality of M1 traces 30 corresponding to the multiple thin film transistor 50 in the same row is the same with the transverse lengths of the portion of the plurality of M1 traces 30 corresponding to the leftmost thin film transistor 50.

The above embodiments describe that the transverse lengths of the portion of the plurality of M1 traces 30 corresponding to one of the plurality of sub-fan-out areas 201 have a same transverse length. In other embodiments, structures of the plurality of sub-fan-out areas 201 may all be arranged according to the structures as shown in FIG. 2 or FIG. 3. That is, the transverse lengths of a portion of the plurality of M1 traces 30 in each of the plurality of sub-fan-out areas 201 are set to be the same, or the transverse lengths of all of the plurality of M1 traces 30 in each of the plurality of sub-fan-out areas 201 are set to be the same.

It should be noted again that, the M1 traces 30 with the same transverse length exist between different sub-fan-out areas 201, thereby the above embodiments describe that the transverse lengths of a portion or all of the plurality of M1 traces 30 in one sub-fan-out area 201 are the same. The plurality of sub-fan-out areas 201 are arranged according to the configuration shown in FIG. 2 or FIG. 3, rather than to set the transverse length of one of the plurality of M1 traces 30 in one of the plurality of sub-fan-out areas 201 to be the same with the transverse length of one of the plurality of M1 traces 30 in other sub-fan-out areas 201.

In at least one embodiment, the transverse lengths of all of the plurality of M1 traces 30 connected to each of the plurality of thin film transistors 50 in the array substrate 100 may be set to be the same, and all of the plurality of M1 traces 30 span an entire row of the plurality of thin film transistors 50. Thus, it is possible to ensure that contact areas between the M1 traces 30 of all of the plurality of thin film transistors 50 and other traces are the same, thereby ensuring that the capacitances of each of the thin film transistors 50 are the same. Thereby the overall uniformity of the picture can be effectively improved when the picture is compensated.

The array substrate 100 further comprises a plurality of sensing lines 40 and a plurality of via holes 60. Each of the plurality of sensing lines 40 generally includes one or more of longitudinal sensing lines 401 and one or more of transverse sensing lines 402. The one or more of transverse sensing lines 402 is disposed above the plurality of thin film transistors 50 and is directly connected with the plurality of thin film transistors 50. A portion of the longitudinal sensing lines 401 are connected to one or more of the plurality of the M1 traces 30 corresponding to each of the plurality of thin film transistors 50. Each of the plurality of thin film transistors 50 is connected to one of the plurality of sensing lines 40. A portion of the longitudinal sensing lines 401 of each of the plurality of thin film transistors 50 are connected to one or more of the plurality of M1 traces 30 corresponding to the each of the plurality of thin film transistors 50 through respective corresponding via holes 60.

It should be noted that, the array substrate 100 further includes a plurality of via holes 60, and the plurality of via holes 60 are configured to connect a plurality of sensing lines and the M1 traces 30, thereby the plurality of via holes 60 need to be arranged in parallel to ensure that the plurality of M1 traces 30 are also arranged in parallel, thereby avoiding conduction problems caused by the extended M1 traces 30 pass through the via holes 60 corresponding to other thin film transistors 50. There are other structures in the array substrate 100, if there are unavoidable via holes 60 of the extended M1 traces 30, it is necessary to disconnect at the unavoidable via holes 60. Of course, the M1 traces 30 corresponding to each of the plurality of thin film transistors 50 cannot be disconnected at via hole 60 corresponding to the each of the plurality of thin film transistors 50, because the M1 traces 30 corresponding to the each of the plurality of thin film transistors 50 need to be connected to the plurality of sensing lines.

Meanwhile, the capacitance is related to the contact area, and the above embodiments of the present disclosure only extends the transverse lengths of the portion of the plurality of M1 traces 30, if the capacitance of each of the plurality of thin film transistors 50 is set to be the same, it is necessary to set the longitudinal width of each of the M1 traces 30 to be the same. Same transverse lengths and same longitudinal widths can ensure the same capacitance of each of the plurality of thin film transistor 50.

It should be noted that, a direction of the transverse lengths in the present disclosure generally refers to a distribution direction of a row of the plurality of thin film transistors 50. M1 traces 30 need to span the plurality of sensing lines, thereby the direction of the transverse length may also be a direction perpendicular to the plurality of sensing lines, and a longitudinal direction is a direction parallel to the plurality of sensing lines. In the present disclosure, each of the plurality of M1 traces 30 to which one of the plurality of thin film transistors 50 is connected actually includes a plurality of metal lines, but transverse lengths of all of the plurality of metal lines are set to be the same regardless of the number of metal lines included in each of the plurality of M1 traces 30.

In the above-described embodiments, the description of each embodiment has its own emphasis, and parts not detailed in one embodiment can be referred to above detailed description of other embodiments, which will not be repeated here.

In specific implementation, the above units or structures can be implemented as independent entities, and can also be arbitrarily combined to be implemented as the same or several entities. The specific implementation of the above units or structures can refer to the above method embodiments, which will not be repeated here.

The specific implementation of above operations can be referred to the above embodiments and will not be repeated here.

The array substrate and the display panel according to embodiments of the present disclosure are described in detail above. The principles and embodiments of the present disclosure have been described with reference to embodiments, and the description of the above embodiments is merely intended to aid in the understanding of the method of the present disclosure and its core idea. At the same time, changes may be made by those skilled in the art to both the specific implementations and the scope of disclosure in accordance with the teachings of the present disclosure. In view of the foregoing, the content of the present specification should not be construed as limiting the disclosure.

What is claimed is:

1. An array substrate comprising:
a pixel area comprising a plurality of thin film transistors arranged in a multi-row and multi-column array; and
a fan-out area comprising a plurality of sub-fan-out areas, wherein each of the plurality of sub-fan-out areas is arranged corresponding to a row of the plurality of thin film transistors, and each of the plurality of sub-fan-out areas is connected to a row of thin film transistors corresponding to the corresponding row of thin film transistors by a plurality of M1 traces;
wherein, transverse lengths of a portion of the plurality of M1 traces connected to different thin film transistors in at least one of the plurality of sub-fan-out areas are the same, and the transverse lengths have a direction same as a distribution direction of a row of the plurality of thin film transistors.

2. The array substrate according to claim 1, wherein transverse lengths of all of the plurality of M1 traces in the at least one of the plurality of sub-fan-out areas are the same.

3. The array substrate according to claim 1, wherein a portion of the plurality of M1 traces in the at least one of the plurality of sub-fan-out areas span a portion of the plurality of thin film transistors.

4. The array substrate according to claim 1, wherein all of the plurality of M1 traces in the at least one of the plurality of sub-fan-out areas span all of the thin film transistors in a row of the plurality of thin film transistors.

5. The array substrate according to claim 1, wherein transverse lengths of a portion of the plurality of M1 traces in each of the plurality of sub-fan-out areas are the same.

6. The array substrate according to claim 1, wherein transverse lengths of all of the plurality of M1 traces in the fan-out area are the same.

7. The array substrate according to claim 1, wherein the array substrate further comprises a plurality of sensing lines and a plurality of via holes, each of the plurality of sensing lines comprises one or more of transverse sensing lines and one or more of longitudinal sensing lines, each of the plurality of thin film transistors is connected to a portion of the longitudinal sensing lines of each of the plurality of sensing lines, and a portion of the longitudinal sensing lines of each of the plurality of thin film transistors are connected to one or more of the plurality of M1 traces corresponding to the each of the plurality of thin film transistors through respective corresponding via holes.

8. The array substrate according to claim 7, wherein the plurality of via holes are arranged in parallel to avoid extended M1 traces pass through the via holes corresponding to other thin film transistors.

9. The array substrate according to claim 1, wherein longitudinal widths of the plurality of M1 traces connected to each of the plurality of thin film transistors are the same.

10. The array substrate according to claim 1, wherein longitudinal width of a portion of the plurality of M1 traces in the at least one of the plurality of sub-fan-out areas are the same.

11. A display panel comprising an array substrate, wherein the array substrate comprises:
a pixel area comprising a plurality of thin film transistors arranged in a multi-row and multi-column array; and
a fan-out area comprising a plurality of sub-fan-out areas, wherein each of the plurality of sub-fan-out areas is arranged corresponding to a row of the plurality of thin film transistors, and each of the plurality of sub-fan-out areas is connected to a row of thin film transistors corresponding to the corresponding row of thin film transistors by a plurality of M1 traces;
wherein transverse lengths of a portion of the plurality of M1 traces respectively connected to different thin film transistors in at least one of the plurality of sub-fan-out areas are the same, and the transverse lengths have a direction same as a distribution direction of a row of the plurality of thin film transistors.

12. The display panel according to claim 1, wherein transverse lengths of all of the plurality of M1 traces in the at least one of the plurality of sub-fan-out areas are the same.

13. The display panel according to claim 1, wherein a portion of the plurality of M1 traces in the at least one of the plurality of sub-fan-out areas span a portion of the plurality of thin film transistors.

14. The display panel according to claim 1, wherein all of the plurality of M1 traces in the at least one of the plurality of sub-fan-out areas span all of the thin film transistors in a row of the plurality of thin film transistors.

15. The display panel according to claim 1, wherein transverse lengths of a portion of the plurality of M1 traces in each of the plurality of sub-fan-out areas are the same.

16. The display panel according to claim 1, wherein transverse lengths of all of the plurality of M1 traces in the fan-out area are the same.

17. The display panel according to claim 1, wherein the array substrate further comprises a plurality of sensing lines and a plurality of via holes, each of the plurality of sensing lines comprises one or more of transverse sensing lines and one or more of longitudinal sensing lines, each of the plurality of thin film transistors is connected to a portion of the longitudinal sensing lines of each of the plurality of sensing lines, and a portion of the longitudinal sensing lines of each of the plurality of thin film transistors are connected to one or more of the plurality of M1 traces corresponding to the each of the plurality of thin film transistors through respective corresponding via holes.

18. The display panel according to claim 7, wherein the plurality of via holes are arranged in parallel to avoid extended M1 traces pass through the via holes corresponding to other thin film transistors.

19. The display panel according to claim 1, wherein longitudinal widths of the plurality of M1 traces connected to each of the plurality of thin film transistors are the same.

20. The display panel according to claim 1, wherein longitudinal width of a portion of the plurality of M1 traces in the at least one of the plurality of sub-fan-out areas are the same.
